(19) United States
(12) Patent Application Publication
(10) Pub. No.: US 2023/0002890 A1
(43) Pub. Date: Jan. 5, 2023

(54) MULTIPLE SURFACE AND FLUORINATED BLOCKING COMPOUNDS

(71) Applicant: Applied Materials, Inc., Santa Clara, CA (US)

(72) Inventors: Mark Saly, Santa Clara, CA (US); Bhaskar Jyoti Bhuyan, San Jose, CA (US)

(73) Assignee: Applied Materials, Inc., Santa Clara, CA (US)

(21) Appl. No.: 17/366,917

(22) Filed: Jul. 2, 2021

(51) Int. Cl. C23C 16/40; C23C 16/455; C23C 16/04

(52) U.S. Cl. CPC C23C 16/401; C23C 16/45536; C23C 16/04

(57) ABSTRACT

Embodiments of the disclosure relate to methods for depositing blocking layers. Some embodiments utilize blocking compounds comprising more than one reactive moiety on a substrate with multiple metallic materials. Some embodiments utilize fluorinated blocking compounds to improve the stability of the blocking layer during subsequent plasma-assisted selective deposition processes.

### TECHNICAL FIELD

Embodiments of the disclosure generally relate to blocking compounds and methods of use thereof for selective deposition. In particular, some embodiments of disclosure relate to blocking compounds comprising multiple reactive moieties and uses thereof. Some embodiments of the disclosure relate to fluorinated blocking compounds and uses thereof.

### BACKGROUND

The semiconductor industry faces many challenges in the pursuit of device miniaturization including the rapid scaling of nanoscale features. Such challenges include the fabrication of complex devices, often using multiple lithography steps and etch processes. Furthermore, the semiconductor industry needs low cost alternatives to high cost EUV for patterning complex architectures. To maintain the cadence of device miniaturization and keep chip manufacturing costs down, selective deposition has shown promise. It has the potential to remove costly lithographic steps by simplifying integration schemes.

Selective deposition can be achieved by blocking a surface with a self-assembled monolayer (SAM) formed from a blocking compound. The head group(s) of the blocking compound plays a crucial role as it participates in the selective chemisorption of the blocking compound on one surface over the other surface. The tail group(s) of blocking compounds are typically alkyl or aryl chains which add spatial bulkiness to the blocking compound to physically and chemically protect the non-targeted surface from deposition precursors.

Selection of appropriate head group(s) enables a blocking compound to block different surfaces. In general, it is easier to enable the selective blocking of dielectrics as most dielectrics contain terminal Si—OH or O—H dangling bonds. In contrast, the blocking of metals requires different reactive groups for different metals as every metal has different electronic structures and behaves differently chemically.

Future integration schemes are becoming increasingly complex and different metal and dielectric materials are often exposed at the same time. To enable selective deposition in these complex environments, there is a need for a blocking compound to block multiple material surfaces at the same time.

Additionally, another major challenge of some selective deposition approaches is the instability of the SAM in plasma environments. As blocking compounds often contain carbonaceous chains as tail group, selective deposition by plasma-based processes can lead to the degradation of the alkyl/aryl chain thereby leading to a loss of selectivity.

In general, the selective deposition of dielectric (e.g., SiO₂, low-k) on dielectric surfaces can enable reduced patterning steps and reduce shorting in lower line space structures. These selective deposition processes can also enable fully landed via (FLV) schemes.

However, there is currently no thermal processes for the deposition of SiO₂ or low-k which are feasible on a production scale. SiO₂ and low-k are typically deposited in PEALD schemes using an O₂ or other plasma. These plasmas ash the alkyl chains of the blocking compounds. Accordingly, there is a need for a new class of blocking compounds that are able to withstand the plasma environment and enable the plasma-based deposition of dielectric on dielectric (e.g., FAV scheme).

### SUMMARY

One or more embodiments of the disclosure are directed to a method of depositing a blocking layer. The method comprises exposing a substrate surface comprising an exposed first metallic material, an exposed second metallic material, and an exposed dielectric material to a blocking compound to selectively form a blocking layer on the first and second metallic materials over the dielectric material. The blocking compound comprises a first moiety and a second moiety which are different and selected from phosphonates, carbon-carbon double bonds, carbon-carbon triple bonds, amines, thiols and silanes.

Additional embodiments of the disclosure are directed to a method of substrate processing comprising exposing a substrate surface comprising an exposed metallic material having a first surface and an exposed dielectric material having a second surface to a fluorinated blocking compound to selectively form a blocking layer on either the first surface or the second surface.

Further embodiments of the disclosure are directed to a selective deposition method comprising exposing a substrate surface comprising an exposed metallic material having a first surface and an exposed dielectric material having a second surface to a fluorinated blocking compound to selectively form a blocking layer on the first surface. A silicon oxide film is selectively deposited on the second surface over the blocking layer by a plasma-enhanced deposition process comprising an oxygenating plasma.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an exemplary substrate during processing according to one or more embodiment of the disclosure; and

FIG. 2 illustrates an exemplary substrate during processing according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, a “patterned substrate” or “multicolor substrate” refers to a substrate with a plurality of different material surfaces. In some embodiments, a patterned substrate comprises at least a first surface and a second surface. In some embodiments, the first surface comprises a dielectric material and the second surface comprises a metallic material. In some embodiments, the first surface comprises a metallic material and the second surface comprises a dielectric material. In some embodiments, the metallic material may be comprised of several different metallic materials each with an exposed surface.

As used in this specification and the appended claims, the terms “reactive gas”, “process gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

Some embodiments of the disclosure provide methods of selective deposition which utilize blocking compounds comprising different reactive moieties. Some embodiments of the disclosure provide methods of selective deposition which utilize fluorinated blocking compounds.

As used in this specification and the appended claims, the term “selectively depositing on a first surface over a second surface”, and the like, means that a first amount of a film or layer is deposited on the first surface and a second amount of film or layer is deposited on the second surface, where the second amount of film is less than the first amount of film, or no film is deposited on the second surface. The term “over” used in this regard does not imply a physical orientation of one surface on top of another surface but rather a relationship of the thermodynamic or kinetic properties of the chemical reaction with one surface relative to the other surface. For example, selectively depositing a cobalt film onto a copper surface over a dielectric surface means that the cobalt film deposits on the copper surface and less or no cobalt film deposits on the dielectric surface; or that the formation of the cobalt film on the copper surface is thermodynamically or kinetically favorable relative to the formation of a cobalt film on the dielectric surface.

In some embodiments, “selectively” means that the subject material forms on the target surface at a rate greater than or equal to about 5×, 10×, 15×, 20×, 25×, 30×, 35×, 40×, 45× or 50× the rate of formation on the non-selected surface. Stated differently, the selectivity for the target material surface relative to the non-selected surface is greater than or equal to about 5:1, 10:1, 15:1, 20:1, 25:1, 30:1, 35:1, 40:1, 45:1 or 50:1.

One strategy to achieve selective deposition employs the use of blocking layers in which a blocking layer is formed on predetermined substrate materials upon which deposition is to be avoided with negligible impact to the substrate material on what deposition is to be achieved. A film can be deposited on the target substrate material while deposition on other substrate materials is “blocked” by the blocking layer. In some embodiments, the blocking layer can be optionally removed without net adverse effects to the deposited film.

Some embodiments of the disclosure incorporate a blocking layer typically referred to as a self-assembled monolayer (SAM) or SAM layer. A self-assembled monolayer (SAM) consists of an ordered arrangement of spontaneously assembled organic molecules (SAM molecules or blocking compounds) adsorbed on a surface. These molecules are typically comprised a moieties with an affinity for the substrate (head group) and a relatively long, inert, linear hydrocarbon moiety (tail group). Some SAM molecules are fundamentally a surfactant which has a hydrophilic functional head with a hydrophobic carbon chain tail.

Blocking layer or SAM formation occurs through the fast adsorption of reactive head groups at the surface and the slow association of tail groups through van der Waals interactions. SAM molecules are chosen such that the head group selectively reacts with the substrate materials to be blocked during deposition. Deposition is then performed, and in some embodiments, the SAMs can be removed, for example through a thermal decomposition (with desorption of any byproducts) or an integration-compatible ashing process.

A representative process flow for selective deposition may include a) providing a patterned substrate, b) growing a SAM (either by CVD, ALD, or immersion), and c) selective deposition (e.g. CVD or ALD) of a film. In the representative process flow, the SAM is used as a sacrificial layer to enable selective deposition.

Fundamentally the SAM growth on a surface is a chemisorption process. Determined by chemisorption kinetics, the coverage of a SAM layer follows the Elovich equation

$$\frac{{d}_{q}}{{d}_{t}} = α exp ( - β q )$$

where q is the amount of chemisorption, t is time, a is the initial rate of chemisorption (mmol/g-min) and β is the desorption constant (g/mmol). Accordingly, the coverage of a SAM layer as the function of time follows an asymptotic trend. As a result, the selectivity of SAM-based depositions follows a similar trend as well (i.e. as coverage increases, selectivity also increases).

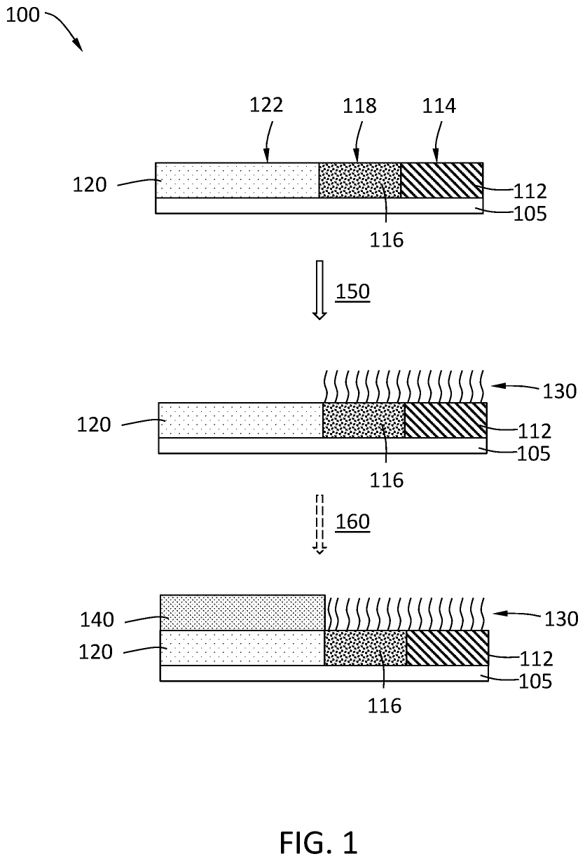

Referring to FIG. 1, one or more embodiment of the disclosure is directed to a processing method 100. A substrate 105 is provided with an exposed first metallic material 112, an exposed second metallic material 116 and an exposed dielectric material 120. The exposed first metallic material 112 has a surface 114, the exposed second metallic material 116 has a surface 118, and the dielectric material 120 has a surface 122. For the avoidance of doubt, the first metallic material 112 and the second metallic material 116 have different elemental compositions.

In some embodiments, the dielectric material 120 comprises or consists essentially of one or more of silicon oxide, silicon nitride, silicon carbide, low-k dielectrics and combinations thereof. In some embodiments, the metallic materials comprise or consist essentially of one or more of copper, cobalt, tungsten, ruthenium, or molybdenum. In some embodiments, the metallic materials comprise or consist essentially of conductive metal nitrides (e.g., titanium nitride). As used in this specification and the appended claims, the term “consists essentially of” means that greater than or equal to about 95%, 98% or 99% of the specified material is the stated material.

Without being bound by theory, the inventors have found that substrate surfaces which contain multiple metallic materials present a unique challenge. Each reactive moiety class reacts well with certain metals, but less effectively or not at all with other metals.

Accordingly, some embodiments of the disclosure relate to blocking compounds which comprise multiple reactive moieties such that differing metallic surfaces can be effectively blocked with a single blocking compound exposure. In some embodiments, the blocking compound comprises a first moiety and a different second moiety. In some embodiments, the first moiety and the second moiety are selected from phosphonates (e.g., acids or esters), carbon-carbon double bonds, carbon-carbon triple bonds, amines, thiols and silanes.

In some embodiments, the first moiety is a phosphonate. In some embodiments, the first moiety is a carbon-carbon double bond or a carbon-carbon triple bond. In some embodiments, the first moiety is an amine. In some embodiments, the first moiety is a thiol. In some embodiments, the first moiety is a silane.

As identified above, each of the reactive moieties reacts best with certain metals. Accordingly, in some embodiments, the first metallic material comprises cobalt or copper and the first moiety is a phosphonate. In some embodiments, the first metallic material comprises copper and the first moiety is a carbon-carbon double bond, or a carbon-carbon triple bond. In some embodiments, the first metallic material comprises cobalt or tungsten and the first moiety is an amine. In some embodiments, the first metallic material comprises copper or ruthenium and the first moiety is a thiol. In some embodiments, the first metallic material comprises tungsten, cobalt, or titanium nitride and the first moiety is a silane.

The reactive moieties may be positioned at any location within the blocking compound. In some embodiments, the blocking compound comprises a carbonaceous tail comprising an alkyl or aryl group (shown as R′ in the examples below). In some embodiments, the first moiety is positioned as a terminal reactive group and the second moiety is spaced 0 to 10 carbon atoms away from the first moiety.

The blocking compound of some embodiments has a general formula of RM₁-SP-RM₂-R′, where RM₁ and RM₂ are the first and second reactive moieties, SP is a spacer comprising 0 to 10 carbon atoms, and R′ is an alkyl or aryl carbonaceous tail group comprising 1 to 18 carbon atoms. In some embodiments, the spacer is branched such that the R′ group attaches to the spacer rather than the second reactive moiety and both the first and second reactive moieties are terminal groups of different branches. In some embodiments, neither the first moiety nor the second moiety are a terminal group, but rather each terminal end of the blocking compound comprises an alkyl or aryl carbonaceous tail. These embodiments may be understood as R′-RM₁-SP-RM₂-R′.

A non-limiting list of exemplary blocking compounds comprising (1) a carbon-carbon double bond or a carbon-carbon triple bond, and (2) an amine are provided below.

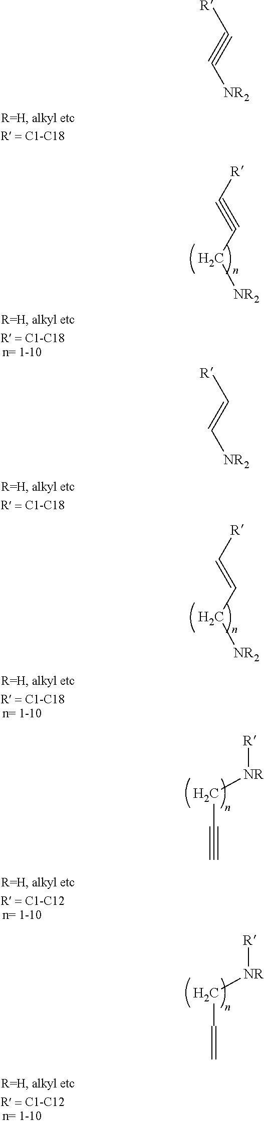

As shown above, the amine moieties may be primary, secondary or even tertiary amines comprising alkyl groups comprising 1 to 6 carbon atoms. Similarly, phosphonate reactive moieties may comprise —OH (phosphonic acid) or —OR (phosphonate esters). In some embodiments, the phosphonate esters may comprise alkyl groups comprising 1 to 6 carbon atoms.

Referring again to FIG. 1, at 150, the substrate 105 is exposed to a blocking compound comprising a first moiety and a second moiety to selectively form a blocking layer 130 on the first metallic material 112 and the second metallic material 116 over the dielectric material 120.

The substrate may be exposed to the blocking compound by any suitable process. In some embodiments, the substrate is exposed to the blocking compound by a chemical vapor deposition (CVD) process. In some embodiments, the substrate is exposed to the blocking compound by an ALD process. In some embodiments, the substrate is exposed to the blocking compound by an immersion or “wet” process.

After formation of the blocking layer 130, the method 100 optionally continues at 160 with the selective deposition of a film 140 on the dielectric surface 122. The amount of the film 140 formed on the surfaces 114, 118 of the first metallic material and the second metallic material, respectively, is less than the amount of the film formed on the dielectric surface 122. A measurement of the amount of film 140 formed on the surfaces can be the average thickness of the film formed on each surface. In some embodiments, the deposition of the film 140 may be described as selectively depositing the film 140 on the dielectric surface 122 over the metallic surfaces 114, 118. While the film 140 depicted in FIG. 1 is not shown on the metallic surfaces 114, 118, those skilled in the art will understand that a small amount of deposition may occur on these surfaces.

In some embodiments, the film 140 comprises a dielectric film. In some embodiments, the film 140 comprises or consists essentially of silicon oxide, silicon nitride, silicon carbide, low-k dielectric or combinations thereof.

The film 140 may be deposited by any suitable process. In some embodiments, the film 140 is deposited by CVD. In some embodiments, the film 140 is deposited by ALD. In some embodiments, the film 140 is deposited by exposing the substrate to a plurality of reactants. In some embodiments, the plurality of reactants is exposed to the substrate separately. In some embodiments, the plurality of reactants is separated temporally.

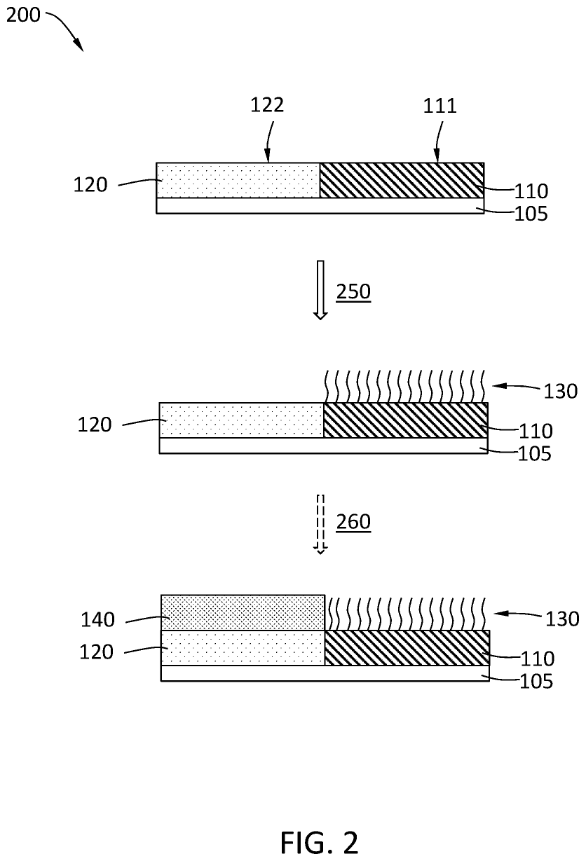

Referring to FIG. 2, some embodiments of the disclosure relate to methods 200 of substrate processing. The method 200 begins at 250 by exposing a substrate 105 comprising a metallic material 110 and a dielectric material 120 to a fluorinated blocking compound to selectively form a blocking layer 130 on either the first surface 111 of the metallic material 110 or the second surface 122 of the dielectric material 120. While formation of the blocking layer 130 on the first surface 111 of the metallic material 110 is shown in FIG. 2, formation on either surface is envisioned by the inventors.

In some embodiments, the blocking layer is selectively formed on the first surface and the fluorinated blocking compound comprises a phosphonate, a carbon-carbon double bond, a carbon-carbon triple bond, an amine, a thiol or a silane. In some embodiments, the blocking layer is selectively formed on the second surface and the fluorinated blocking compound comprises a silyl amine, a silyl alkoxide, or a silyl halide.

Metallic material 110 may comprises any of the metallic materials identified above with respect to metallic materials 112 and 116. Dielectric material 120 is the same dielectric material 120 identified above.

Without being bound by theory, the inventors have found that fluorine is a key component in fire retardants and that these materials cannot easily be oxidized. Accordingly, the inventors have tailored blocking compounds with fluorine containing alkyl chains to enable blocking layers capable of surviving strongly oxidizing environments.

In some embodiments, the method 200 utilizes a fluorinated blocking compound. The fluorinated blocking compound has a general formula of A-L, where A is a reactive head group and L is an alkyl or aryl carbonaceous tail group comprising 1 to 18 carbon atoms. The fluorinated blocking compound contains at least one fluorine atom within the tail group. In some embodiments, the tail group is a perfluoro group where each hydrogen atom is replaced with a fluorine atom. In some embodiments, the fluorinated blocking compound comprises a ratio of fluorine atoms to hydrogen atoms within the tail group greater than or equal to 1:10, greater than or equal to 1:5, greater than or equal to 1:2, greater than or equal to 1:1, greater than or equal to 2:1, greater than or equal to 5:1, or greater than or equal to 10:1. In some embodiments, the ratio is less than or equal to 10:1, less than or equal to 5:1, less than or equal to 2:1, less than or equal to 1:1, less than or equal to 1:2, less than or equal to 1:5, or less than or equal to 1:10.

After formation of the blocking layer 130, the method 200 optionally continues at 260 with the selective deposition of a film 140 on the first surface 111 or the second surface 122 over the blocking layer 130.

In some embodiments, the film 140 comprises a metal film. In some embodiments, the film 140 comprises a dielectric film. In some embodiments, the film 140 comprises or consists essentially of silicon oxide, silicon nitride, silicon carbide, low-k dielectric or combinations thereof.

The film 140 may be deposited by any suitable process. In some embodiments, the film 140 is deposited by CVD. In some embodiments, the film 140 is deposited by ALD. In some embodiments, the film 140 is deposited by exposing the substrate to a plurality of reactants. In some embodiments, the plurality of reactants is exposed to the substrate separately. In some embodiments, the plurality of reactants is separated temporally. In some embodiments, the plurality of reactants is separated spatially.

In some embodiments, the film 140 is deposited by a plasma-assisted deposition process. In some embodiments, the plasma of the plasma-assisted deposition process comprises an oxygenating plasma. In some embodiments, the oxygenating plasma comprises 02.

The plasma may be generated by any suitable means, including but not limited to, remote plasma and direct plasma. The plasma may be an inductively coupled plasma (ICP) or conductively coupled plasma (CCP). The plasma has a power in a range of 5 W to 2000 W, in a range of 100 W to 1500 W, in a range of 200 W to 1000 W, in a range of 300 W to 800 W, in a range of 400 W to 600 W, or in a range of 450 W to 550 W.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a blocking layer, the method comprising exposing a substrate surface comprising an exposed first metallic material, an exposed second metallic material and an exposed dielectric material to a blocking compound to selectively form a blocking layer on the first and second metallic materials over the dielectric material, the blocking compound comprising a first moiety and a second moiety, the first moiety and the second moiety being different and selected from phosphonates, carbon-carbon double bonds, carbon-carbon triple bonds, amines, thiols and silanes.

2. The method of claim 1, wherein the exposed metallic materials are selected from cobalt, copper, tungsten, ruthenium and molybdenum.

3. The method of claim 1, wherein the first moiety is a phosphonate.

4. The method of claim 1, wherein the first moiety is a carbon-carbon double bond or a carbon-carbon triple bond.

5. The method of claim 1, wherein the first moiety is an amine.

6. The method of claim 1, wherein the first moiety is a thiol.

7. The method of claim 1, wherein the first metallic material comprises cobalt or copper and the first moiety is a phosphonate.

8. The method of claim 1, wherein the first metallic material comprises copper and the first moiety is a carbon-carbon double bond, or a carbon-carbon triple bond.

9. The method of claim 1, wherein the first metallic material comprises cobalt or tungsten and the first moiety is an amine.

10. The method of claim 1, wherein the first metallic material comprises copper or ruthenium and the first moiety is a thiol.

11. The method of claim 1, wherein the first metallic material comprises tungsten or cobalt and the first moiety is a silane.

12. A method of substrate processing comprising exposing a substrate surface comprising an exposed metallic material having a first surface and an exposed dielectric material having a second surface to a fluorinated blocking compound to selectively form a blocking layer on either the first surface or the second surface.

13. The method of claim 12, wherein the blocking layer is selectively formed on the first surface and the fluorinated blocking compound comprises a phosphonic acid, a carbon-carbon double bond, a carbon-carbon triple bond, an amine, a thiol or a silane.

14. The method of claim 12, wherein the blocking layer is selectively formed on the second surface and the fluorinated blocking compound comprises a silyl amine, a silyl alkoxide, or a silyl halide.

15. The method of claim 12, wherein the fluorinated blocking compound has a ratio of fluorine atoms to hydrogen atoms of greater than or equal to 1:1 within a tail group of the fluorinated blocking compound.

16. The method of claim 12, further comprising selectively depositing a film on the first surface or the second surface over the blocking layer.

17. The method of claim 16, wherein the film is deposited by a plasma-assisted deposition process.

18. The method of claim 17, wherein the plasma-assisted deposition process comprises exposing the substrate surface to an oxygenating plasma.

19. The method of claim 18, wherein the film comprises silicon oxide.

20. A selective deposition method comprising:
exposing a substrate surface comprising an exposed metallic material having a first surface and an exposed dielectric material having a second surface to a fluorinated blocking compound to selectively form a blocking layer on the first surface; and
selectively depositing a silicon oxide film on the second surface over the blocking layer, the silicon oxide film deposited by a plasma-enhanced deposition process comprising an oxygenating plasma.
